(19) United States
(12) Patent Application Publication
(10) Pub. No.: US 2025/0280628 A1
(43) Pub. Date: Sep. 4, 2025

(54) MULTICOLOR LIGHT SOURCE DEVICE AND MANUFACTURING METHOD THEREOF

(71) Applicant: Hon Hai Precision Industry Co., Ltd., New Taipei City (TW)

(72) Inventors: Fu-He Hsiao, New Taipei City (TW); Wen-Chien MIAO, New Taipei City (TW); Tzu-Yi Lee, New Taipei City (TW); Yu-Heng HONG, New Taipei City (TW); Hao-Chung KUO, New Taipei City (TW)

(73) Assignee: Hon Hai Precision Industry Co., Ltd., New Taipei City (TW)

(21) Appl. No.: 18/752,823

(22) Filed: Jun. 25, 2024

(30) Foreign Application Priority Data
Mar. 4, 2024 (TW) 113107635

(51) Int. Cl. H01L 33/24; H01L 25/075; H01L 33/38; H01L 33/50; H01L 33/62

(52) U.S. Cl. CPC H10H 20/821; H01L 25/0753; H10H 20/831; H10H 20/8512; H10H 20/857; H10H 20/032; H10H 20/0361; H10H 20/0364

(57) ABSTRACT

Disclosed is a multicolor light source device including a substrate, a light-emitting frame, a plurality of light-emitting nanorods, and at least one wavelength conversion layer. The light-emitting frame is configured on the substrate and surrounds at least one containing space. The plurality of light-emitting nanorods are configured on the substrate and located in the at least one containing space. The light-emitting frame and the plurality of light-emitting nanorods are a plurality of light-emitting diode stacks of a same light-emitting color. The at least one wavelength conversion layer is configured in the at least one containing space and between the plurality of light-emitting nanorods. A manufacturing method of a multicolor light source device

### CROSS-REFERENCE TO RELATED APPLICATION

This application claims the priority benefit of Taiwan application serial no. 113107635, filed on Mar. 4, 2024. The entirety of the above-mentioned patent application is hereby incorporated by reference herein and made a part of this specification.

### BACKGROUND

### Technical Field

The disclosure relates to a light source device and a manufacturing method thereof, and in particular to a multicolor light source device and a manufacturing method thereof.

### Description of Related Art

As optoelectronic technologies improve, light-emitting diodes (LEDs) may be made smaller and smaller. Micro-light-emitting diodes (micro-LEDs) are thus created. Micro-LEDs of different colors may even be arranged in arrays to form sub-pixels of display panels, thereby creating micro-LED displays.

However, there are relatively more challenges in the integration of micro-LED displays using micro-LED chips of the three primary colors (red, green, and blue), which is also relatively costly. In addition, miniature-sized red micro-LEDs have a low light efficiency. Thus, the color purity and color gamut of the micro-LED displays integrated with micro-LED chips of the three primary colors (red, green, and blue) are also affected.

### SUMMARY

The disclosure provides a multicolor light source device having a high light efficiency and a low cost. The multicolor light source device is also capable of emitting a light with a higher color purity.

The disclosure provides a manufacturing method of a multicolor light source device, through which a multicolor light source device with a high light efficiency and a low cost may be manufactured, and the multicolor light source device is capable of emitting a light with a higher color purity.

In an embodiment of the disclosure, a multicolor light source device is provided. The multicolor light source device includes a substrate, a light-emitting frame, a plurality of light-emitting nanorods, and at least one wavelength conversion layer. The light-emitting frame is configured on the substrate and defines at least one containing space. The plurality of light-emitting nanorods are configured on the substrate and located in the at least one containing space. The light-emitting frame and the plurality of light-emitting nanorods are a plurality of light-emitting diode stacks of a same light-emitting color. The at least one wavelength conversion layer is configured in the at least one containing space and between the plurality of light-emitting nanorods.

In an embodiment of the disclosure, a manufacturing method of a multicolor light source device is provided. The manufacturing method includes the following steps. A substrate is provided. A mask is formed on the substrate, and the mask has a plurality of holes. A light-emitting frame and a plurality of light-emitting nanorods are grown on the substrate and out of the plurality of holes. The light-emitting frame defines at least one containing space. The plurality of light-emitting nanorods are located in the at least one containing space. The light-emitting frame and the plurality of light-emitting nanorods are a plurality of light-emitting diode stacks of a same light-emitting color. Further, at least one wavelength conversion layer is filled in the at least one containing space and between the plurality of light-emitting nanorods.

In an embodiment of the disclosure, a multicolor light source device is provided. The multicolor light source device includes a substrate, a light-emitting frame, a plurality of light-emitting nanorods, and a plurality of wavelength conversion layers. The light-emitting frame is configured on the substrate and includes an outer part and a dividing part. The outer part surrounds a plurality of containing spaces. The dividing part is connected to an inner side of the outer part and divides the plurality of containing spaces. The plurality of light-emitting nanorods are configured on the substrate and located in the plurality of containing spaces. The light-emitting frame and the plurality of light-emitting nanorods are a plurality of blue light light-emitting diode stacks. The plurality of wavelength conversion layers are separately configured in the plurality of containing spaces and located between the plurality of light-emitting nanorods. The plurality of wavelength conversion layers include a red wavelength conversion layer and a green wavelength conversion layer.

For the multicolor light source device and the manufacturing method thereof in the embodiment of the disclosure, the light-emitting frame is adopted or formed to emit a light of a color. The plurality of light-emitting nanorods are adopted or formed to excite the wavelength conversion layer configured in the containing space and between the plurality of light-emitting nanorods, thereby forming a light of another color. Thus, the multicolor light source device not only has a high light efficiency and a low cost but is also capable of emitting a light with a higher color purity. In addition, by filling the wavelength conversion layer in a gap between the plurality of light-emitting nanorods, a contact surface area between the wavelength conversion layer and the plurality of light-emitting nanorods is increased, which improves a wavelength conversion effect and reduces an element thickness required for an additional wavelength conversion layer.

### BRIEF DESCRIPTION OF THE DRAWINGS

FIG. 1 is a three-dimensional schematic diagram of a multicolor light source device in an embodiment of the disclosure.

FIG. 2 is a top schematic diagram of a part of the multicolor light source device in FIG. 1.

FIG. 3 is a cross-sectional schematic diagram of the multicolor light source device in FIG. 2 along Line I-I.

FIG. 4 is a partially enlarged cross-sectional schematic diagram of FIG. 3.

FIGS. 5A and 5B are partially enlarged cross-sectional schematic diagrams showing a process of a manufacturing method of a multicolor light source device in an embodiment of the disclosure.

### DESCRIPTION OF THE EMBODIMENTS

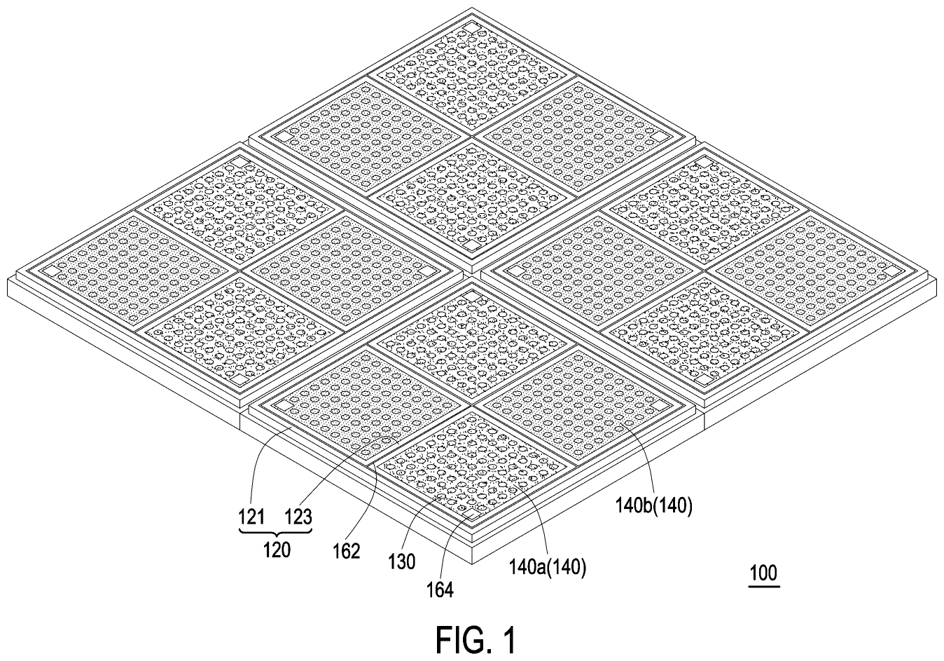

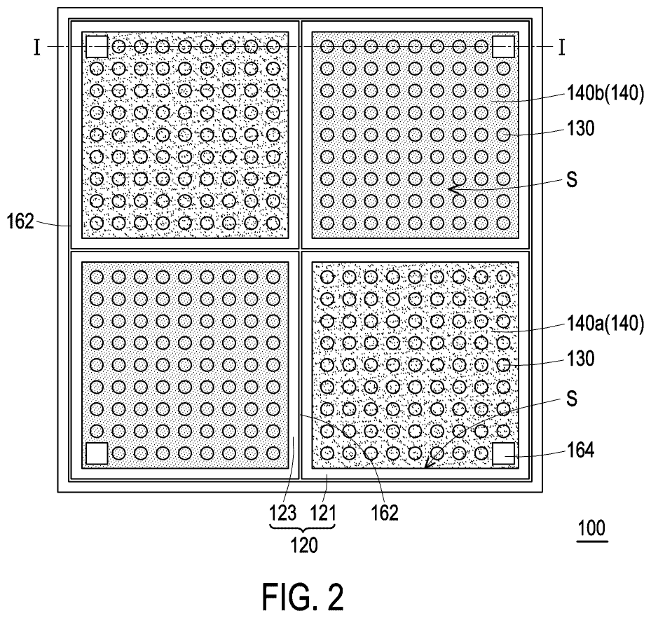

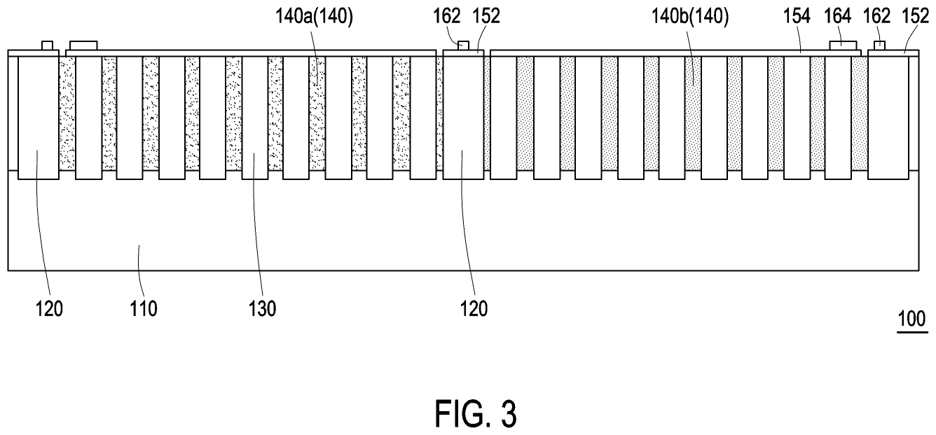

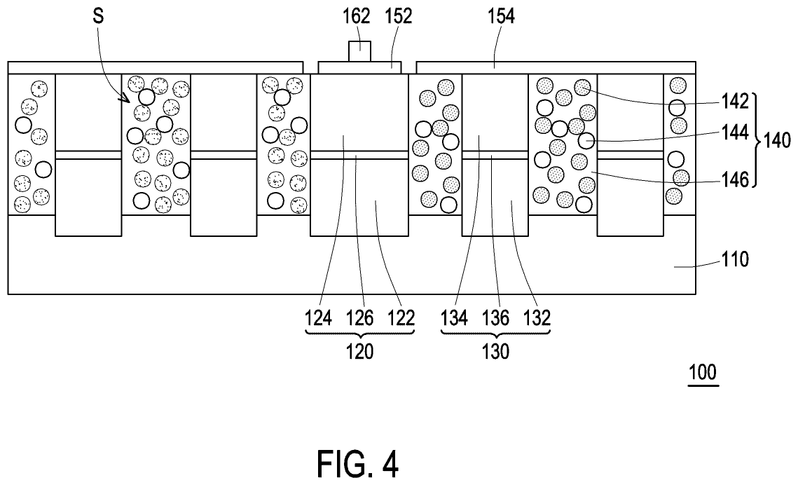

FIG. 1 is a three-dimensional schematic diagram of a multicolor light source device in an embodiment of the disclosure. FIG. 2 is a top schematic diagram of a part of the multicolor light source device in FIG. 1. FIG. 3 is a cross-sectional schematic diagram of the multicolor light source device in FIG. 2 along Line I-I. FIG. 4 is a partially enlarged cross-sectional schematic diagram of FIG. 3. Referring to FIGS. 1 to 4, a multicolor light source device 100 in this embodiment includes a substrate 110, a light-emitting frame 120, a plurality of light-emitting nanorods 130, and at least one wavelength conversion layer 140 (a plurality of wavelength conversion layers 140 are used for the examples of FIG. 2). The light-emitting frame 120 is configured on the substrate 110 and defines at least one containing space S (a plurality of containing spaces S are used for the examples of FIG. 2). The plurality of light-emitting nanorods 130 are configured on the substrate 110 and located in the containing space S. The light-emitting frame 120 and the plurality of light-emitting nanorods 130 are a plurality of light-emitting diode (LED) stacks of the same light-emitting color (e.g., a plurality of blue light LED stacks). That is, the light-emitting frame 120 and the plurality of light-emitting nanorods 130 are used to emit blue light. However, in other embodiments, the light-emitting frame 120 and the plurality of light-emitting nanorods 130 may be used to emit ultraviolet light. For example, the light-emitting frame 120 includes a first type semiconductor layer 122, a second type semiconductor layer 124, and a light-emitting layer 126 configured between the first type semiconductor layer 122 and the second type semiconductor layer 124. The light-emitting nanorod 130 includes a first type semiconductor layer 132, a second type semiconductor layer 134, and a light-emitting layer 136 configured between the first type semiconductor layer 132 and the second type semiconductor layer 134. The first type semiconductor layers 122 and 132 are, for example, N-type semiconductor layers. The second type semiconductor layers 124 and 134 are, for example, P-type semiconductor layers. However, in other embodiments, the first type semiconductor layers 122 and 132 may be P-type semiconductor layers, and the second type semiconductor layers 124 and 134 may be N-type semiconductor layers. In addition, the light-emitting layers 126 and 136 are, for example, quantum well layers or multi-quantum well layers.

The at least one wavelength conversion layer 140 is configured in the at least one containing space S and between the plurality of light-emitting nanorods 130. In this embodiment, the plurality of wavelength conversion layers 140 are separately configured in the plurality of containing spaces S. In this embodiment, the wavelength conversion layer 140 includes a plurality of quantum dots 142. In the embodiment of FIG. 4, the wavelength conversion layer 140 includes a mixture of a plurality of quantum dots 142 and a plurality of nanoparticles 144. For example, the wavelength conversion layer 140 may further include a photoresist 146, and the plurality of quantum dots 142 are mixed into the photoresist 146 with the plurality of nanoparticles 144.

For the multicolor light source device 100 in this embodiment, the light-emitting frame 120 is adopted to emit light of a color. The plurality of light-emitting nanorods 130 are adopted to excite the wavelength conversion layer 140 configured in the containing space S and between the plurality of light-emitting nanorods 130, thereby forming light of another color. Thus, the multicolor light source device 100 not only has a high light efficiency and a low cost but is also capable of emitting light with higher color purity. For example, the light-emitting frame 120 and the light-emitting nanorod 130, as blue light LEDs, have a high light efficiency. Red light and green light may be formed after the blue light emitted from the light-emitting nanorod 130 excites the wavelength conversion layer 140. Hence, the problems of a low red light efficiency and low color purity resulting from the adoption of red light miniature LEDs are avoided. Further, the cost of this embodiment is lower than the integration of LED chips of three colors (red, green, and blue). In addition, when a size of an element is reduced to the level of a miniature LED, the blue light LED still has a good light efficiency. Through the wavelength conversion layer 140, a good light efficiency of the three colors red, green, and blue may be maintained in a miniature size, which is advantageous in terms of the next-generation displays. Moreover, the quantum dots have better performance in color and light-emitting purity, wavelength conversion efficiency, and uniformity compared to conventional phosphors. In addition, by filling the wavelength conversion layer 140 in a gap between the plurality of light-emitting nanorods 130, a contact surface area between the wavelength conversion layer 140 and the plurality of light-emitting nanorods 130 is increased, which improves a wavelength conversion effect and reduces an element thickness required for an additional wavelength conversion layer.

In addition, the light extraction rate may be increased by adopting the nanoparticle 144 in the wavelength conversion layer 140. In this embodiment, the nanoparticle 144 is, for example, a wide band gap particle or a scattering particle. The nanoparticle 144 is, for example, a silver particle whose surface is covered by a layer of silicon dioxide film. By adjusting the concentration of the nanoparticle 144 and the quantum dot 142, the light-emitting effect and wavelength conversion efficiency may be effectively improved, but the disclosure is not limited to thereto. However, in another embodiment, the nanoparticle 144 may not be adopted in the wavelength conversion layer 140. Instead, a method of doping the quantum dot 142 into the photoresist 146 is adopted, thereby forming the wavelength conversion layer 140.

In this embodiment, the multicolor light source device 100 further includes a transparent conductive layer 154, a first electrode 162, and a second electrode 164. The transparent conductive layer 154 is configured on top of the plurality of light-emitting nanorods 130 and electrically connected to the plurality of light-emitting nanorods 130. The first electrode 162 is configured on top of the light-emitting frame 120, and the second electrode 164 is configured on top of the transparent conductive layer 154. In this embodiment, the first electrode 162 may be configured on top of the light-emitting frame 120 and electrically connected to the light-emitting frame 120 through the transparent conductive layer 152. In this embodiment, the substrate 110 is, for example, a conductive substrate, or the upper surface of the substrate 110 may be covered by a conductive layer. By forming a voltage difference between the substrate 110 (or the conductive layer thereon) and the first electrode 162 and forming a voltage difference between the substrate 110 (or the conductive layer thereon) and the second electrode 164, the light-emitting frame 120 and the light-emitting nanorod 130 may be driven to emit light.

In this embodiment, the light-emitting frame 120 includes an outer part 121 and a dividing part 123. The outer part 121 surrounds the plurality of containing spaces S. The dividing part 123 is connected to the inner side of the outer part 121 and divides the plurality of containing spaces S. In this embodiment, the plurality of wavelength conversion layers 140 include a plurality of wavelength conversion layers 140 of different colors (e.g., a red wavelength conversion layer 140a and a green wavelength conversion layer 140b), which are separately configured in the plurality of different containing spaces S. In this embodiment, red light and green light are formed after the blue light emitted by the light-emitting nanorod 130 excites the red wavelength conversion layer 140a and the green wavelength conversion layer 140b respectively. In FIG. 1, the multicolor light source device 100 is shown with a 2×2 array of light-emitting frames 120 as an example, but in practice, the multicolor light source device 100 may include more light-emitting frames 120 arranged in arrays. Each light-emitting frame 120 and the light-emitting nanorod 130 and the wavelength conversion layer 140 therein form a pixel. A plurality of pixels arranged in arrays forms a color display or a white illumination source. That is, site selection and zone control may be performed by each pixel independently to effectively control whether a single pixel emits light, the intensity of the light emitted, and multi-wavelength adjustment, enabling the realization of functions such as full-color display or white light illumination. In another embodiment, the multicolor light source device 100 may also serve as a light source for optical communication. One or more pixels may form a transmission channel for optical communication, and a light signal is formed through the light in different color ratios emitted from the pixel(s). In addition, the number of channels covering the entire visible light range may be designed to increase the transmission capacity and rate. In this way, an integral system with functions including display, illumination, and communication may be realized through the multicolor light source device 100 in this embodiment.

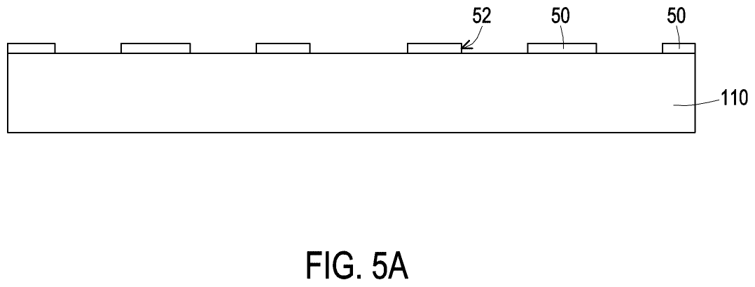

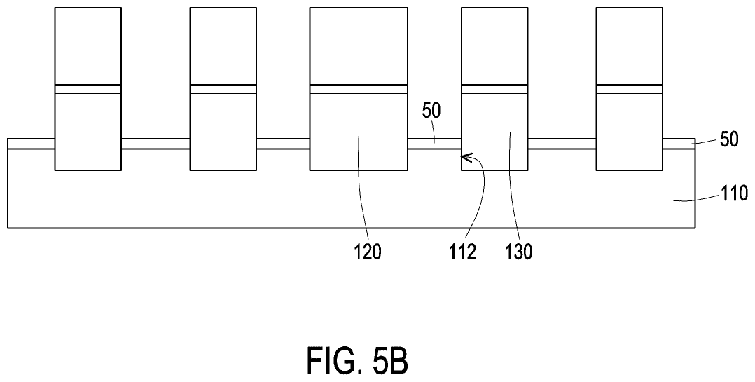

FIGS. 5A and 5B are partially enlarged cross-sectional schematic diagrams showing a process of a manufacturing method of a multicolor light source device in an embodiment of the disclosure. Referring to FIGS. 5A and 5B, the manufacturing method of the multicolor light source device in this embodiment can be used to manufacture the multicolor light source device 100 in each of the above embodiments. The manufacturing method of the multicolor light source device in this embodiment includes the following steps. First, referring to FIG. 5A, a substrate 110 is provided. Subsequently, a mask 50 is formed on the substrate 110, and the mask 50 has a plurality of holes 52. Referring to FIG. 5B, in an embodiment, the substrate 110 may then be etched through the plurality of holes 52 to form a plurality of recesses 112. Then, a light-emitting frame 120 and a plurality of light-emitting nanorods 130 are grown on the substrate 110 and out of the plurality of holes 52. The light-emitting frame 120 surrounds at least one containing space S. The plurality of light-emitting nanorods 130 are located in the at least one containing space S. This may be referred to in FIG. 2. In addition, the light-emitting frame 120 and the plurality of light-emitting nanorods 130 are a plurality of LED stacks of the same light-emitting color. In this embodiment, the light-emitting frame 120 and the plurality of light-emitting nanorods 130 are grown from the plurality of recesses 112 through the plurality of holes 52, that is, by selective growth or regrowth. However, in other embodiments, the plurality of recesses 112 may not be formed first by etching the substrate 110. Instead, the light-emitting frame 120 and the plurality of light-emitting nanorods 130 may be selectively grown from a flat surface of the substrate 110 through the plurality of holes 52 with the help of the mask 50.

Thereafter, referring to FIG. 4, the mask 50 may be removed in an embodiment. Further, at least one wavelength conversion layer 140 is filled in the at least one containing space S and between the plurality of light-emitting nanorods 130. In another embodiment, the mask 50 may not be removed. Instead, the at least one wavelength conversion layer 140 is not only filled in the at least one containing space S and between the plurality of light-emitting nanorods 130 but also above the mask 50.

Thereafter, in this embodiment, the transparent conductive layer 154 is formed on top of the plurality of light-emitting nanorods 130. In addition, the first electrode 162 is formed on top of the light-emitting frame 120, and the second electrode 164 is formed on top of the transparent conductive layer 154 (as shown in FIG. 3). In this embodiment, before the first electrode 162 is formed on top of the light-emitting frame 120, a transparent conductive layer 152 may be formed on top of the light-emitting frame 120 first. Then, the first electrode 162 is formed on the transparent conductive layer 152. In this way, the multicolor light source device 100 in this embodiment is manufactured.

In summary, for the multicolor light source device and the manufacturing method thereof in the embodiment of the disclosure, the light-emitting frame is adopted or formed to emit a light of a color. The plurality of light-emitting nanorods are adopted or formed to excite the wavelength conversion layer configured in the containing space and between the plurality of light-emitting nanorods, thereby forming a light of another color. Thus, the multicolor light source device not only has a high light efficiency and a low cost but is also capable of emitting a light with a higher color purity. In addition, by filling the wavelength conversion layer in a gap between the plurality of light-emitting nanorods, a contact surface area between the wavelength conversion layer and the plurality of light-emitting nanorods is increased, which improves a wavelength conversion effect and reduces an element thickness required for an additional wavelength conversion layer.

What is claimed is:

1. A multicolor light source device, comprising:
a substrate;
a light-emitting frame, configured on the substrate and defining at least one containing space;
a plurality of light-emitting nanorods, configured on the substrate and located in the at least one containing space, wherein the light-emitting frame and the plurality of light-emitting nanorods are a plurality of light-emitting diode stacks of a same light-emitting color; and
at least one wavelength conversion layer, configured in the at least one containing space and between the plurality of light-emitting nanorods.

2. The multicolor light source device of claim 1, wherein the at least one containing space comprises a plurality of containing spaces, and the light-emitting frame comprises:
an outer part, surrounding the plurality of containing spaces; and
a dividing part, connected to an inner side of the outer part and dividing the plurality of containing spaces.

3. The multicolor light source device of claim 1, further comprising:
a transparent conductive layer, configured on a top of the plurality of light-emitting nanorods and electrically connected to the plurality of light-emitting nanorods;
a first electrode, configured on a top of the light-emitting frame; and
a second electrode, configured on a top of the transparent conductive layer.

4. The multicolor light source device of claim 1, wherein the at least one containing space comprises a plurality of containing spaces, and the at least one wavelength conversion layer comprises a plurality of wavelength conversion layers of a different color, the plurality of wavelength conversion layers being separately configured in the plurality of different containing spaces.

5. The multicolor light source device of claim 1, wherein the at least one wavelength conversion layer comprises a plurality of quantum dots.

6. The multicolor light source device of claim 1, wherein the at least one wavelength conversion layer comprises a mixture of a plurality of quantum dots and a plurality of nanoparticles.

7. The multicolor light source device of claim 1, wherein the light-emitting frame and the plurality of light-emitting nanorods are used to emit a blue light.

8. A manufacturing method of a multicolor light source device, comprising:
providing a substrate;
forming a mask on the substrate, wherein the mask has a plurality of holes;
growing a light-emitting frame and a plurality of light-emitting nanorods on the substrate and out of the plurality of holes, wherein the light-emitting frame defines at least one containing space, and the plurality of light-emitting nanorods are located in the at least one containing space, the light-emitting frame and the plurality of light-emitting nanorods being a plurality of light-emitting diode stacks of a same light-emitting color; and
filling at least one wavelength conversion layer in the at least one containing space and between the plurality of light-emitting nanorods.

9. The manufacturing method of the multicolor light source device of claim 8, further comprising:
etching the substrate through the plurality of holes to form a plurality of recesses before the light-emitting frame and the plurality of light-emitting nanorods are grown on the substrate and out of the plurality of holes, wherein the light-emitting frame and the plurality of light-emitting nanorods are grown from the plurality of recesses.

10. The manufacturing method of the multicolor light source device of claim 8, wherein the at least one containing space comprises a plurality of containing spaces, and the light-emitting frame comprises:
an outer part, surrounding the plurality of containing spaces; and
a dividing part, connected to an inner side of the outer part and dividing the plurality of containing spaces.

11. The manufacturing method of the multicolor light source device of claim 8, further comprising:
forming a transparent conductive layer on a top of the plurality of light-emitting nanorods;
forming a first electrode on a top of the light-emitting frame; and
forming a second electrode on a top of the transparent conductive layer.

12. The manufacturing method of the multicolor light source device of claim 8, wherein the at least one containing space comprises a plurality of containing spaces, and the at least one wavelength conversion layer comprises a plurality of wavelength conversion layers of a different color, the plurality of wavelength conversion layers being separately configured in the plurality of different containing spaces.

13. The manufacturing method of the multicolor light source device of claim 8, wherein the at least one wavelength conversion layer comprises a plurality of quantum dots.

14. The manufacturing method of the multicolor light source device of claim 8, wherein the at least one wavelength conversion layer comprises a mixture of a plurality of quantum dots and a plurality of nanoparticles.

15. The manufacturing method of the multicolor light source device of claim 8, wherein the light-emitting frame and the plurality of light-emitting nanorods are used to emit a blue light.

16. The manufacturing method of the multicolor light source device of claim 8, further comprising:
removing the mask after the light-emitting frame and the plurality of light-emitting nanorods are grown on the substrate and out of the plurality of holes.

17. A multicolor light source device, comprising:
a substrate;
a light-emitting frame, configured on the substrate and comprising:
an outer part, surrounding a plurality of containing spaces; and
a dividing part, connected to an inner side of the outer part and dividing the plurality of containing spaces;
a plurality of light-emitting nanorods, configured on the substrate and located in the plurality of containing spaces, wherein the light-emitting frame and the plurality of light-emitting nanorods are a plurality of blue light light-emitting diode stacks; and
a plurality of wavelength conversion layers, separately configured in the plurality of containing spaces and located between the plurality of light-emitting nanorods, wherein the plurality of wavelength conversion layers comprise a red wavelength conversion layer and a green wavelength conversion layer.

18. The multicolor light source device of claim 17, further comprising:
a plurality of transparent conductive layers, separately configured in an upper part of the plurality of containing spaces and located on a top of the plurality of light-emitting nanorods, wherein the plurality of transparent conductive layers are electrically connected to the plurality of light-emitting nanorods;
a first electrode, configured on a top of the light-emitting frame; and
a plurality of second electrodes, configured on a top of the plurality of transparent conductive layers.

19. The multicolor light source device of claim 17, wherein the plurality of wavelength conversion layers comprise a plurality of quantum dots.

20. The multicolor light source device of claim 17, wherein the plurality of wavelength conversion layers comprise a mixture of a plurality of quantum dots and a plurality of nanoparticles.
